(19) United States
(12) Patent Application Publication
(10) Pub. No.: US 2003/0043654 A1
(43) Pub. Date: Mar. 6, 2003

(54) Method for accessing memory cells of a DRAM memory module

(76) Inventors: Johann Pfeiffer, Ottobrunn (DE); Bernd Klehn, Unterhaching (DE); Helmut Fischer, Oberhaching (DE)

Correspondence Address: LERNER AND GREENBERG, P.A., POST OFFICE BOX 2480, HOLLYWOOD, FL, 33022-2480, US

(21) Appl. No.: 10/234,076

(22) Filed: Sep. 3, 2002

(30) Foreign Application Priority Data
Sep. 1, 2001 (DE) 101 43 033.7

(51) Int. Cl. G11C 7/00

(52) U.S. Cl. 365/200

(57) ABSTRACT

A method for accessing memory cells of a cell field of a DRAM module organized in rows and columns, in which an addressed row is addressed over a word line, and a desired column is addressed over a bit line pair, is described. For a write access, a stored charge is transferred to all bit line pairs, a column address is detected by a column decoder, the appertaining word line is activated, and a read amplifier amplifies the potential on the addressed bit lines. The write access is initiated simultaneously with an activation of the word line.

### BACKGROUND OF THE INVENTION

1. Field of the Invention

The present invention relates to a method for accessing memory cells of a cell field of a dynamic random access memory (DRAM) module that is organized in rows and columns. In the DRAM module, an addressed row is addressed by way of a word line, and a desired column is addressed by way of a bit line pair. In a write access operation, a stored charge is transferred to all bit line pairs, a column address is determined by a column decoder, the appertaining word line is activated, and a read amplifier amplifies the potential on the addressed bit lines.

DRAM modules are characterized in that they need a certain capacity in order to store an information bit. In contrast to static memory modules (SRAM), which are utilized in caches, DRAM memory modules have the disadvantage that the bit that is read from the cell must be rewritten after a read access so that the cell contents remain stable. A distinction is therefore made between the access time after which a data content is delivered back to the CPU and the DRAM cycle time indicating the time interval after which a memory module can be accessed again.

Besides this, DRAM memory modules require refresh cycles at intervals in the millisecond range, which guarantee that the data contents are not lost when the cell is not accessed for a long period of time.

Because of this characteristic, standard DRAM memory modules are some ten times slower than SRAM memory modules, whose cell contents remain stable. The speed disadvantage of DRAM memory modules can be partly compensated for by special access techniques.

In most DRAM memory modules, the addresses are multiplexed and transferred in the module in two successive portions in order to save address lines. DRAM memory modules are internally built as rectangular grids of rows and columns. For each addressed bit, the row is first addressed by way of external lines with the aid of a signal row address strobe (RAS). With the signal column address strobe (CAS), the column is addressed over the same lines. The access time is thus the total of the row access time and the column access time. Absent optimization, this equals 120 ns today. Various access modes that are standard in all DRAM memory modules accelerate the DRAM access. A NIBBLE mode delivers the three next bits for each RAS signal that is set without the signal having to be reset. In a page mode, the RAS signal need not be reapplied every time in order to address data within a row. This currently allows access times of approximately 60 ns for accessing the bits of a row or page. In a static column mode, the CAS signal also need not be reset each time in order to access data within a row.

Recently, various DRAM memory module versions with improved access behavior have been developed. An EDO-RAM memory module supports address pipelining, since addressed data are available at the bus for a longer time. The bits of a row that is buffered in the chip and that has been addressed once can be accessed more rapidly in the page mode than with standard memory modules. EDO-RAM memory modules shorten the access to data within a page to approximately 25 ms.

What are known as synchronous DRAM modules (SDRAM modules) allow the burst accessing of a specified length within sequential DRAM areas. Rather than synchronization signals, a rapid clock signal provides for the correct sequence of the DRAM access. This shortens the data access time to approximately 8 to 10 nanoseconds (ns).

RAMBUS memory modules forgo the RAS/CAS signals. Instead, an SDRAM core is provided with a new 8-bit-wide bus access interface that is synchronized with the CPU clock. Over the interface, each chip as well as a complete memory bank can be driven. Successive bytes are outputted by a chip at intervals of less than two ns. With the parallel accessing of several chips, main memory systems with bandwidths of up to several gigabytes/second can be realized.

What is known as banking is also employed in DRAM memory modules. This method is also referred to as interleaf memory. Here, n successive data words are stored in different banks, respectively, which are successively accessed. In this case only the access time, and not the cycle time, must be taken into account in burst accessing. A DRAM controller assigns successive memory addresses to different banks. Only after n accesses is the first bank reaccessed.

The below-described problem exists with all the foregoing variants of the DRAM memory. In the reading of memory cells from a cell field, a minimum wait time between the activate command for activating a word line and the write command is specified in the context of the typical specification. The reason for the wait time is the need to wait for the development of the memory cells along a word line which are read out in the activation operation. Therefore, a certain amount of time elapses after the cell field transistors are opened. Only afterward is the read amplifier activated for the purpose of amplifying the accompanying signals, whereupon the data are released for reading or, in a write operation, for writing.

2. Summary of the Invention

It is accordingly an object of the invention to provide a method for accessing memory cells of a DRAM memory module which overcomes the above-mentioned disadvantages of the prior art methods of this general type, which guarantees shorter access times than have been possible in the past.

With the foregoing and other objects in view there is provided, in accordance with the invention, a method for accessing memory cells of a cell field of a dynamic random access memory (DRAM) module organized in rows and columns. The method includes addressing a row over a respective word line, addressing a desired column over a bit line pair, and initiating a write access simultaneously with an activation of the respective word line. The write access includes transferring a stored charge to all bit line pairs, determining a column address using a column decoder, activating the respective word line, and using a read amplifier for amplifying a potential on addressed bit lines.

Because the invention provides that the write operation is initiated in the cell field simultaneously with the activation of the word line, the read amplifiers which are to receive the write data can be overwritten without the cell data having to be evaluated beforehand. In all other read amplifiers of an activated word line, the usual evaluation of the bit line signals occurs. This brings increased speed in the operation of the memory module.

It is conceivable that the number of address pins will be higher in future DRAM memory modules. For example, this can be achieved with the aid of ball grid arrays, whereby word line addresses and column addresses can be transferred simultaneously in this case also, resulting in an appreciable gain in speed here as well.

Another advantage of the inventive method is that current is saved, because only part of the read amplifiers need to be charged according to the inventive method, namely that part which will be overwritten in the subsequent write access, and therefore recharging currents are not needed for the read amplifiers.

The advantage of the inventive idea of transferring word line addresses and memory addresses at the same time is that errors in a word line (i.e. in a CSL line) can be purposefully detected and therefore purposefully eliminated without having to replace the entire line with a redundant line. The inventive method thereby allows high flexibility in the repairing of word lines. Alternatively, the invention guarantees a reduction of redundant word line and/or CSL line structures, and therefore the chip surface area can be appreciably reduced.

In accordance with the invention, the DRAM module can be organized as a SDRAM module or a RAMBUS module.

With the foregoing and other objects in view there is further provided, in accordance with the invention, a method for accessing memory cells of a cell field of a dynamic random access memory (DRAM) module organized in rows and columns. The method includes addressing a row over a respective word line, addressing a desired column over a bit line pair, transferring a stored charge to all bit line pairs, determining a column address using a column decoder, activating the respective word line and simultaneously writing to the respective word line, and using a read amplifier for amplifying a potential on addressed bit lines.

Other features which are considered as characteristic for the invention are set forth in the appended claims.

Although the invention is illustrated and described herein as embodied in a method for accessing memory cells of a DRAM memory module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a DRAM based main memory according to the invention;

FIG. 2 is a timing diagram for reading a 0 from a DRAM cell; and

FIG. 3 is a timing diagram for writing a 1 into the DRAM cell.

### DESCRIPTION OF THE PREFERRED EMBODIMENTS

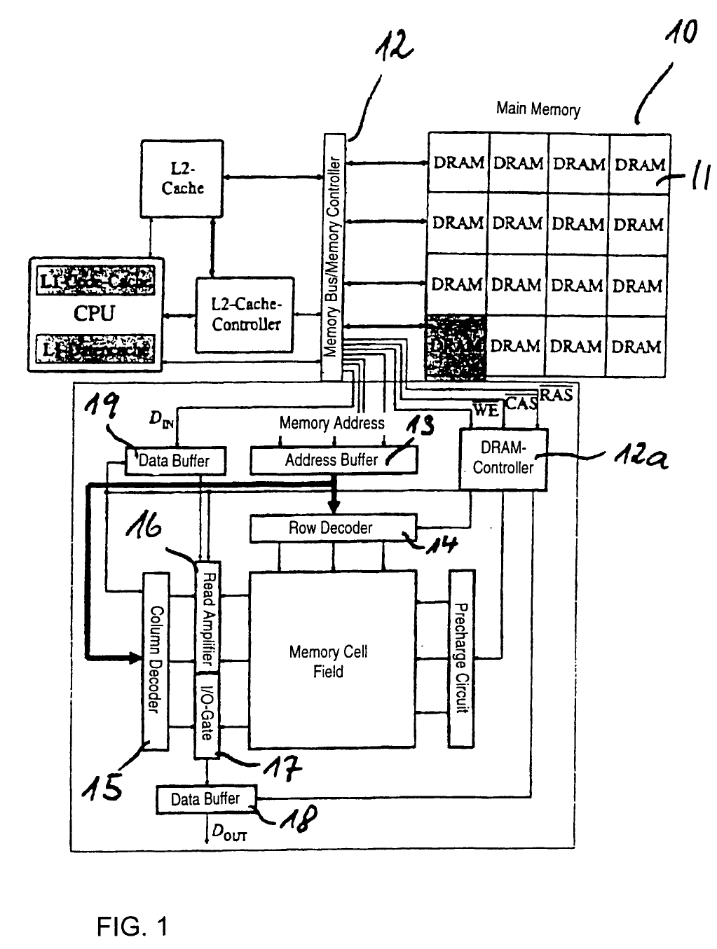

Referring now to the figures of the drawing in detail and first, particularly, to FIG. 1 thereof, there is shown an overall organization of a dynamic random access memory (DRAM) subsystem for a microcomputer. A main memory 10 is built from several identical DRAM chips, referenced DRAM, a representative of which is given reference number 11. The DRAM chips 11 can be located in different banks. A DRAM controller 12 ascertains the bank and the addressed individual chips from the physical memory address and delivers the address signals that the access mode requires.

To access the DRAM chip, the RAS, CAS, and potentially the write enable signal are transferred to a DRAM controller 12a. The RAS signal is activated. An address buffer 13 picks up the row address. From the row address, a row decoder 14 determines the addressed row in the memory cell field of the respective chip 11, which is addressed over a word line WLⱼ. Next, the CAS signal is activated and the DRAM controller 12a writes the column address into the address buffer 13. A column decoder 15 determines the desired column within the cell field, which is addressed over a bit line pair Blᵢ and /Blᵢ. In a read access, a read bit is outputted from the memory cell, amplified by a read amplifier 16, and written into a data output buffer 18 by way of an I/O gate 17. The read bit is the outputted signal Dₒᵤₜ of the DRAM chip.

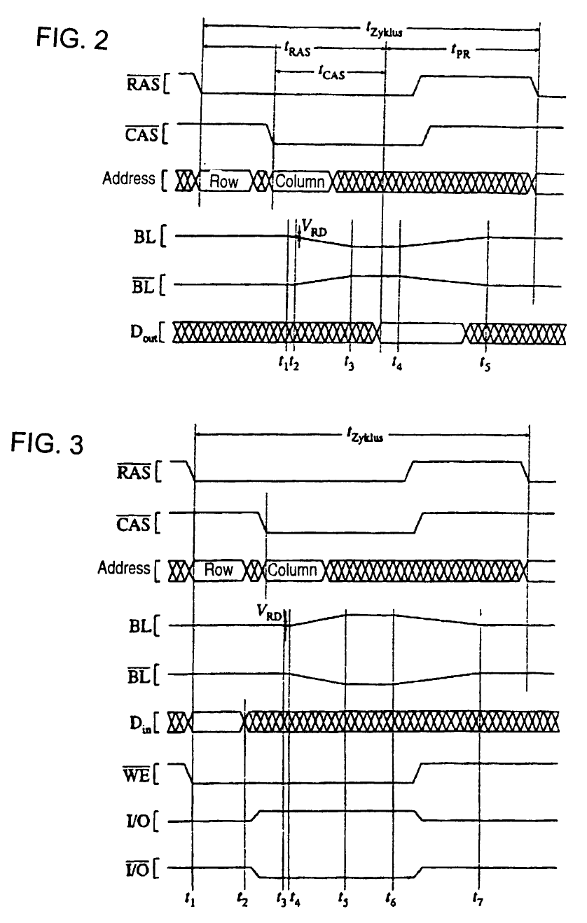

During a write access, the DRAM controller 12a activates the write enable (/WE) signal. Write information Dᵢₙ is transferred to a data buffer 19. The information is routed to the addressed memory cell by way of the I/O gate 17 and the read amplifier 16 and stored. FIG. 2 represents the time sequence for reading a value 0 from the DRAM memory cell 11. A tiny potential difference in the signal of the bit line emerges in the read operation. Given an empty capacitor (0), the potential drops somewhat; otherwise (1) it rises. The read amplifier 17 intensifies this effect over the two bit lines in the corresponding direction. The data are available in stable form for a short time.

FIG. 3 represents a write operation. In the writing of a 1, the write information Dᵢₙ and the /WE signal are simultaneously set with the aid of the /RAS signal. In the input buffer, the signal is amplified and transferred to the line pair I/O and /I/O. The row decoder 14 activates the relevant word line. The stored charge is first transferred to all accompanying pairs. After the /CAS signal is set, and the column address which was transferred to the address buffer 13 is detected by the column decoder, the relevant read amplifier 16 intensifies the potential on the addressed bit lines BLi and /BLi. The previously stored value is then replaced by the amplified new signal. The logic of the DRAM cell is configured such that all other cells of the driven row simultaneously refresh the signal they are already storing as well.

The prior method for accessing the DRAM memory cells has been described with reference to FIGS. 2 and 3. In addition, it has been common in the reading of memory cells from the cell field of a DRAM to wait a minimum time between an activate command (activation of a word line) and a write command in the context of customary specifications. The reason for the wait time is to wait for the developing of the memory cells along a word line that are being read out in the activation. For example, a certain time elapses after the cell field transistors are opened, whereupon the read amplifier is activated for purposes of amplifying the bit line signals, and then the data are released for reading or, given a write command, for overwriting. In contrast, according to the invention, the write operation is initiated in the cell field simultaneously with the activation of the word line. Therefore the read amplifiers that are to receive write data can be overwritten without the cell data having to be evaluated beforehand. In all conventional read amplifiers of an activated word line, on the other hand, the previously customary evaluation of the accompanying signals occurs. Speed is thus gained in the operation of the DRAM memory module, and a small amount of current is saved, because only a reduced number of read amplifiers and bit lines must be overwritten in the subsequent write access.

With the inventive simultaneous transfer of the word line address and the column address, a word line can be repaired with substantially greater flexibility than previously by resorting to redundant lines, or alternatively due to a reducing of the chip area for correspondingly redundant lines.

For example, in the case of CSL redundancy with four segments, a redundant CSL line can replace any CSL line in any of the segments. This can be achieved by falling back on four of what are known as fuse boxes, whereby each fuse box is responsible for a segment. When a CSL line is defective and is replaced with a redundant CSL line in a segment, the fuses of the relevant fuse box are shot. The CSL line is then replaced in this and only this segment by the redundant CSL line; i.e. a repair can still be performed in any of the other three segments. Thus, in the present example, four repairs can be performed with one redundant CSL line.

In principle, the same applies to word line redundancy. Defective word lines have long been replaced entirely with a redundant word line. This is necessary because at the time of the activate command for the word line it is not yet known which CSL line will be activated with a subsequent read or write command. But if, in addition to the word line address, the CSL address can be purposefully accessed with an activate command, as according to the inventive method, it is then known which sector is defective, and the partly defective word line can be segmented just as the CSL line above.

We claim:

1. A method for accessing memory cells of a cell field of a dynamic random access memory (DRAM) module organized in rows and columns, which comprises the steps of:
addressing a row over a respective word line;
addressing a desired column over a bit line pair;
transferring a stored charge to all bit line pairs;
determining a column address using a column decoder;
activating the respective word line and simultaneously writing to the respective word line; and
using a read amplifier for amplifying a potential on addressed bit lines.

2. The method according to claim 1, which comprises organizing the DRAM module as a synchronous DRAM module.

3. The method according to claim 1, which comprises organizing the DRAM module as a RAMBUS memory module.

4. The method according to claim 1, which comprises during a repair procedure, accessing redundant word lines and segments of word lines are accessed for repair purposes.

5. A method for accessing memory cells of a cell field of a dynamic random access memory (DRAM) module organized in rows and columns, which comprises the steps of:
addressing a row over a respective word line;
addressing a desired column over a bit line pair;
initiating a write access simultaneously with an activation of the respective word line, by the steps of:
transferring a stored charge to all bit line pairs;
determining a column address using a column decoder;
activating the respective word line; and
using a read amplifier for amplifying a potential on addressed bit lines.

6. The method according to claim 5, which comprises organizing the DRAM module as a synchronous DRAM module.

7. The method according to claim 5, which comprises organizing the DRAM module as a RAMBUS memory module.

8. The method according to claim 5, which comprises during a repair procedure, accessing redundant word lines and segments of word lines are accessed for repair purposes.
